(19) United States
(12) Patent Application Publication
(10) Pub. No.: US 2026/0188254 A1
(43) Pub. Date: Jul. 2, 2026

(54) LIGHT EMITTING DISPLAY APPARATUS

(71) Applicant: LG Display Co., Ltd., Seoul (KR)

(72) Inventors: Chung-Sik KONG, Paju-si (KR); Hyun-Gi SHIN, Paju-si (KR); Ji-Hui KU, Paju-si (KR); Min-Ha KANG, Paju-si (KR); Meen-Woo KIM, Paju-si (KR); Hyun-Bin JEON, Paju-si (KR); Yoo-Sung JIN, Paju-si (KR); Seok-Joon CHOI, Paju-si (KR); Hye-Jin CHAE, Paju-si (KR); Hyun-Kyu LEE, Paju-si (KR); Jae-Chang KANG, Paju-si (KR); Yun-Seon HWANG, Paju-si (KR); Tae-Hwa SHIN, Paju-si (KR); Seoung-Uk HEO, Paju-si (KR)

(73) Assignee: LG Display Co., Ltd., Seoul (KR)

(21) Appl. No.: 19/414,882

(22) Filed: Dec. 10, 2025

(30) Foreign Application Priority Data
Dec. 30, 2024 (KR) 10-2024-0200604

(51) Int. Cl. G09G 3/3266; G06F 3/041

(52) U.S. Cl. CPC G09G 3/3266; G06F 3/04182

(57) ABSTRACT

A light emitting display apparatus includes a display panel including pixels, a light emitting diode and a plurality of transistors electrically connected to the light emitting diode, in the pixel, and an emission driving circuit including an emission stage which includes a first buffer portion configured to output an emission control signal applied to the pixel, wherein the first buffer portion includes a first buffer transistor connected to a Q1 node and receiving a gate low voltage, a second buffer transistor connected to a QB1 node and receiving a gate high voltage, and a plurality of capacitors connected in parallel with each other between the QB1 node and a first output terminal that is between the first and second buffer transistors.

### CROSS-REFERENCE TO RELATED APPLICATIONS

The present application claims the priority benefit of Korean Patent Application No. 10-2024-0200604 filed in Republic of Korea on Dec. 30, 2024, which is hereby incorporated by reference in its entirety for all purposes as if fully set forth herein.

### BACKGROUND

### Technical Field

The present disclosure relates to a light emitting display apparatus.

### Description of the Related Art

As the information society develops, a demand for display apparatuses for displaying images have increased in various forms, and in recent years, various flat display apparatuses such as organic light emitting display apparatuses and liquid crystal display apparatuses have been used.

A gate driving circuit of a light emitting display apparatus outputs an emission control signal to perform an emission operation. A variation between a high voltage and a low voltage of the emission control signal acts as a noise on a touch element of the light emitting display apparatus.

### BRIEF SUMMARY

The present disclosure provides a light emitting display apparatus that can reduce a touch noise by reducing a rapid variation of voltage in an emission control signal.

Additional features and technical improvements of the disclosure will be set forth in the description which follows, and in part will be apparent from the description, or may be learned by practice of the disclosure. These and other features of the disclosure will be realized and attained by the structure particularly pointed out in the written description and claims hereof as well as the appended drawings.

As embodied and broadly described herein, a light emitting display apparatus includes a display panel including pixels, a light emitting diode and a plurality of transistors electrically connected to the light emitting diode, in the pixel, and an emission driving circuit including an emission stage which includes a first buffer portion configured to output an emission control signal applied to the pixel, wherein the first buffer portion includes a first buffer transistor connected to a Q1 node and receiving a gate low voltage, a second buffer transistor connected to a QB1 node and receiving a gate high voltage, and a plurality of capacitors connected in parallel with each other between the QB1 node and a first output terminal that is between the first and second buffer transistors.

In another aspect, a light emitting display apparatus includes a display panel including pixels, a light emitting diode and a plurality of transistors electrically connected to the light emitting diode, in the pixel, and an emission driving circuit including an emission stage which includes a first buffer portion configured to output an emission control signal applied to the pixel, wherein the first buffer portion includes a first buffer transistor connected to a Q1 node and receiving a gate low voltage, a second buffer transistor connected to a QB1 node and receiving a gate high voltage, and a plurality of Q capacitors connected in parallel with each other between the Q1 node and a first output terminal that is between the first and second buffer transistors.

In yet another aspect, a light emitting display apparatus includes a display panel including pixels, a light emitting diode and a plurality of transistors electrically connected to the light emitting diode, in the pixel, and an emission stage which outputs an emission control signal applied to the pixel, wherein the emission stage includes a first buffer transistor connected to a Q1 node and receiving a gate low voltage, a second buffer transistor connected to a QB1 node and receiving a gate high voltage, and a plurality of capacitors connected in parallel with each other between the QB1 node and a first output terminal that is between the first and second buffer transistors, and/or a plurality of Q capacitors connected in parallel with each other between the Q1 node and the first output terminal.

It is to be understood that both the foregoing general description and the following detailed description are examples and explanatory and are intended to provide further explanation of the disclosure including the claims.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view schematically illustrating a light emitting display apparatus according to a first embodiment of the present disclosure;

FIG. 2 is a circuit view schematically illustrating an example of a pixel according to a first embodiment of the present disclosure;

FIG. 3 is a view illustrating a configuration of a gate driving portion of a light emitting display apparatus according to a first embodiment of the present disclosure;

FIG. 4 is a view schematically illustrating a structure of an emission stage of an emission driving circuit according to a first embodiment of the present disclosure;

FIG. 5 is a view illustrating waveforms of voltage falling at a QB1 node according to presence or absence of a diode and a number of a capacitor(s) in an emission stage according to a first embodiment of the present disclosure;

FIG. 6 is a view illustrating times of voltage falling at a QB1 node according to presence or absence of a diode and a number of a capacitor(s) in an emission stage according to a first embodiment of the present disclosure;

FIG. 7 is a view illustrating waveforms of voltage rising at a first output terminal according to presence or absence of a diode and a number of a capacitor(s) in an emission stage according to an embodiment of the present disclosure;

FIG. 8 is a view illustrating times of voltage rising at a first output terminal according to presence or absence of a diode and a number of a capacitor(s) in an emission stage according to a first embodiment of the present disclosure;

FIG. 9 is a cross-sectional view schematically illustrating an example of a cross-sectional structure of a display panel according to a first embodiment of the present disclosure;

FIG. 10 is a view schematically illustrating an example of a structure of an emission stage of an emission driving circuit according to a second embodiment of the present disclosure;

FIG. 11 is a view illustrating waveforms of voltage falling at a Q1 node according to presence or absence of a diode and a number of a Q capacitor(s) in an emission stage according to a second embodiment of the present disclosure;

FIG. 12 is a view illustrating times of voltage falling at a Q1 node according to presence or absence of a diode and a number of a Q capacitor(s) in an emission stage according to a second embodiment of the present disclosure;

FIG. 13 is a view illustrating waveforms of voltage rising at a first output terminal according to presence or absence of a diode and a number of a Q capacitor(s) in an emission stage according to a second embodiment of the present disclosure;

FIG. 14 is a view illustrating times of voltage rising at a first output terminal according to presence or absence of a diode and a number of a Q capacitor(s) in an emission stage according to a second embodiment of the present disclosure; and

FIG. 15 is a view schematically illustrating an example of a structure of an emission stage of an emission driving circuit according to a third embodiment of the present disclosure.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and these embodiments allow the present disclosure to be complete. The present disclosure is provided to fully inform the scope of the disclosure to the skilled in the art of the present disclosure, and the present disclosure includes those of the claims.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, if it is determined that a detailed description of the related known technology unnecessarily obscure the subject matter of the present disclosure, the detailed description thereof can be omitted. When ‘comprising’, ‘including’, ‘having’, ‘consisting of’, and the like are used in this disclosure, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

In describing components of the present disclosure, terms such as first, second and the like can be used. These terms are only for distinguishing the components from other components, and an essence, order, sequence, or number of the components is not limited by the terms.

Respective features of various embodiments of the present disclosure can be partially or wholly connected to or combined with each other and can be technically interlocked and driven variously, and respective embodiments can be independently implemented from each other or can be implemented together with a related relationship.

Hereinafter, embodiments of the present disclosure are described in detail with reference to the drawings. Meanwhile, in the following embodiments, the same and like reference numerals are assigned to the same and like components, and detailed descriptions thereof can be omitted.

### First Embodiment

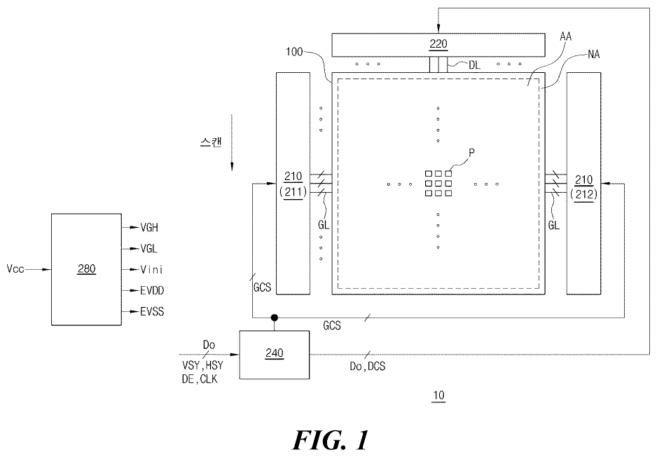

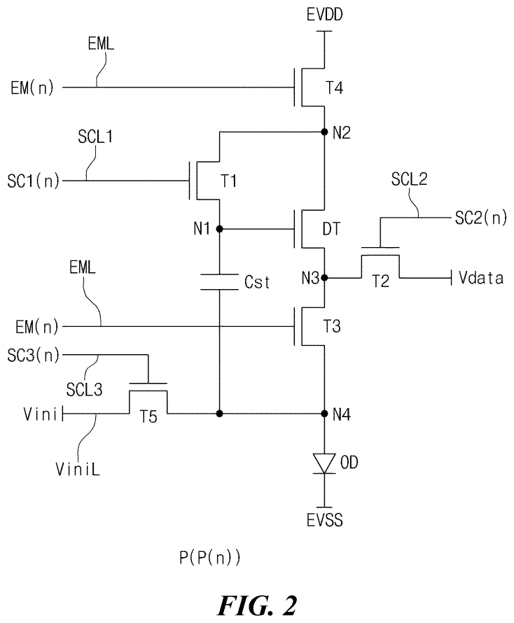

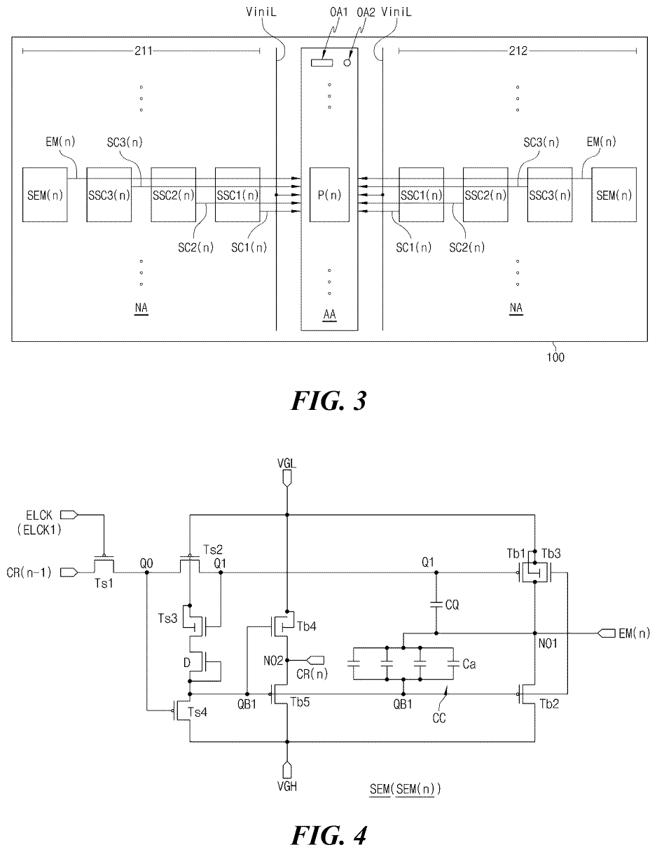

FIG. 1 is a view schematically illustrating a light emitting display apparatus according to a first embodiment of the present disclosure. FIG. 2 is a circuit view schematically illustrating an example of a pixel according to a first embodiment of the present disclosure. FIG. 3 is a view illustrating a configuration of a gate driving portion of a light emitting display apparatus according to a first embodiment of the present disclosure.

Prior to a specific description, an organic light emitting display apparatus is described as an example of the light emitting display apparatus 10.

Referring to FIGS. 1 to 3, the light emitting display apparatus 10 of this embodiment can include a display panel 100 and a driving circuit portion that drives the display panel 100.

Here, the driving circuit portion can include, for example, a gate driving portion (or gate driving circuit) 210, a data driving portion (or data driving circuit) 220, and a timing control portion (or timing control circuit) 240. In addition, the driving circuit portion can include a power supply portion (or power supply circuit) 280 that supplies power for driving the display panel 100, the gate driving portion 210, the data driving portion 220, and the timing control portion 240.

The display panel 100 can include a display region AA that displays an image, and a non-display region NA arranged outside the display region AA (or surrounding the display region AA).

In the display region AA, a plurality of pixels P can be arranged in a matrix form along a plurality of horizontal lines (or row lines) and a plurality of vertical lines (or column lines).

Here, the plurality of pixels P can include pixels that display different colors, for example, red, green, and blue pixels that display red, green, and blue, respectively, but not limited thereto.

In the display panel 100, various signal lines that transmit driving signals for driving the pixels P can be formed on a substrate.

In this regard, for example, a plurality of data lines DL that transmit data signals (or data voltages) which are image signals can extend in the vertical direction and be connected to the pixels P of the respective vertical lines.

In addition, a gate line GL that transmits a gate signal (or gate voltage) can extend in the horizontal direction and be connected to the pixel P of the corresponding horizontal line.

In this embodiment, a plurality of gate signals can be used to drive each pixel P, for example, a first scan signal SC1 to a third scan signal SC3, and an emission control signal EM can be used. Accordingly, a plurality of gate lines GL respectively transmitting the plurality of gate signals can be used, for example, a first scan line SCL1 to a third scan line SCL3, and an emission control line EML can be used.

As such, the plurality of pixels P can be defined by the plurality of data lines DL and gate lines GL intersecting each other.

Each pixel P can include a light emitting diode OD as a light emitting element, and a plurality of transistors and at least one capacitor for driving the light emitting diode OD.

Meanwhile, in this embodiment, for convenience of explanation, a 6T1structure in which the pixel P is equipped with six transistors T1 to T5 and DT and one capacitor Cst as illustrated in FIG. 2 is taken as an example.

Referring to FIG. 2, the pixel P can include a plurality of switching transistors, for example, first transistor T1 to fifth transistor T5, a driving transistor DT, a storage capacitor C, and the light emitting diode OD.

Each of the first to fifth transistors T1 to T5 and the driving transistor DT can include a first electrode, a second electrode, and a gate electrode. One of the first electrode and the second electrode can be a source electrode, and the other of the first electrode and the second electrode can be a drain electrode.

Each of the first to fifth transistors T1 to T5 and the driving transistor DT can be a P-type or N-type transistor. Meanwhile, in FIG. 2, an example is given in which the first to fifth transistors T1 to T5, and the driving transistor DT are configured as N-type transistors, but not limited thereto.

The first transistor T1 to the fifth transistor T5 and the driving transistor DT can include semiconductors of the same material or can include semiconductors of different materials. In this regard, for example, some of the first transistor T1 to the fifth transistor T5 and the driving transistors DT can have one semiconductor layer among a polycrystalline silicon layer, an oxide semiconductor layer, and an amorphous silicon layer, and another some of the first transistor T1 to the fifth transistor T5 and the driving transistors DT can have another semiconductor layer among a polycrystalline silicon layer, an oxide semiconductor layer, and an amorphous silicon layer.

An oxide semiconductor has excellent off-current characteristics, and a polycrystalline silicon has excellent mobility. In this embodiment, an example is given in which each of the first, second, and fifth transistors T1, T2, and T5, and the driving transistor DT can have an oxide semiconductor layer, and the third and fourth transistors T3 and T4 can have a polycrystalline silicon layer, but not limited thereto.

Meanwhile, for convenience of explanation, the pixel P of FIG. 2 can be a pixel P(n) of an n-th horizontal line driven by gate signals output from an n-th stage of the gate driving portion 210.

In this regard, as the gate signals provided to the n-th horizontal line, for example, three scan signals, a first scan signal (SC1: SC1(n)) to a third scan signal (SC3: SC3(n)), and an emission control signal (EM: EM(n)) can be provided.

In this case, in the display region AA, first to third scan lines SCL1 to SCL3, and an emission control line EML that are connected to the n-th stage and transmit the first to third scan signals SC1(n) to SC3(n), and the emission control signal EM(n) to the pixel P(n) can be arranged. Alternatively, the gate driving 210 can be configured to provide two emission control signals EM, which are individually applied to the third and fourth transistors T3 and T4, instead of one emission control signal EM(n).

The first transistor T1 can function as a sampling transistor, the second transistor T2 can function as a data supply transistor, the third and fourth transistors T3 and T4 can function as emission control transistors, and the fifth transistor T5 can function as an initialization transistor.

The light emitting diode OD can include an anode electrode and a cathode electrode. The anode electrode of the light emitting diode OD can be connected to a fourth node N4, and the cathode electrode of the light emitting diode OD can be applied with a low-potential driving voltage EVSS.

The driving transistor DT can include, for example, a first electrode connected to a third node N2, a second electrode connected to a second node N2, and a gate electrode connected to a first node N1. The driving transistor DT can provide a driving current to the light emitting diode OD based on a voltage of the first node N1 (i.e., a voltage stored in the storage capacitor Cst).

The first transistor T1 can include a first electrode connected to the first node N1, a second electrode connected to the second node N2, and a gate electrode receiving the first scan signal SC1(n). The first transistor T1 can be turned on in response to the first scan signal SC1(n), so that the driving transistor DT can be in a diode-connection state in which the gate electrode and the drain electrode of the driving transistor DT are electrically short-circuited, and a threshold voltage of the driving transistor DT can be sampled. The sampled threshold voltage of the driving transistor DT can be reflected into the first node N1.

The storage capacitor Cst can be connected between the first node N1 and a fourth node N4. The storage capacitor Cst can store and maintain a voltage applied to the gate electrode of the driving transistor DT. For convenience of explanation, an electrode of the storage capacitor Cst connected to the first node N1 can be referred to as a first electrode, and an electrode of the storage capacitor Cst connected to the fourth node N4 can be referred to as a second electrode.

The second transistor T2 can include a second electrode connected to the data line DL (or receiving the data voltage Vdata), a first electrode connected to the third node N3, and a gate electrode receiving the second scan signal SC2(n). The second transistor T2 can be turned on in response to the second scan signal SC2(n) and can transmit the data voltage Vdata to the third node N3. In this case, the data voltage Vdata applied to the third node N3 can be reflected to the first node N1 in the turn-on state of the first transistor T1, and as a result, the data voltage Vdata can be reflected to the gate electrode of the driving transistor DT.

The third and fourth transistors T3 and T4 can be connected between a line that transmits a high-potential driving voltage EVDD, and the light emitting diode OD, and can form a current path along which the driving current generated by the driving transistor DT flows.

The third transistor T3 can include a second electrode connected to the driving transistor DT at the third node N3, a first electrode connected to the light emitting diode OD at the fourth node N4, and a gate electrode receiving the corresponding n-th emission control signal EM(n).

The fourth transistor T4 can include a second electrode receiving the high-potential driving voltage EVDD, a first electrode connected to the second node N2, and a gate electrode receiving the emission control signal EM(n).

The third and fourth transistors T3 and T4 can be turned on in response to the emission control signal EM(n). With both the third and fourth transistors T3 and T4 turned on, the driving current can be supplied to the light emitting diode OD, and the light emitting diode OD can emit light at a luminance corresponding to the driving current.

The fifth transistor T5 can include a second electrode connected to an initialization voltage line ViniL that transmits an initialization voltage Vini, a first electrode connected to the fourth node N4, and a gate electrode that receives the third scan signal SC3(n).

The fifth transistor T5 can be turned on in response to the third scan signal SC3(n), and the initialization voltage Vini can be applied to the anode electrode of the light emitting diode OD (i.e., the fourth node N4). Accordingly, the anode electrode of the light emitting diode OD can be initialized (or reset) with the initialization voltage Vini.

The 6T1structure of the pixel P described above is an example, and the pixel P of this embodiment can be configured with a different structure, for example, 7T1, 8T1, or the like.

Referring to FIG. 1, the timing control portion 240 can process image data Do input from a host system to be suitable for size, resolution, etc., of the display panel 100 and supply the processed image data Do to the data driving portion 220. The timing control portion 240 can generate a gate control signal GCS and a data control signal DCS using synchronization signals input from the host system, for example, a dot clock signal CLK, a data enable signal DE, a horizontal synchronization signal HSY, and a vertical synchronization signal VSY. By supplying the gate control signal GCS and the data control signal DCS generated in this way to the gate driving portion 210 and the data driving portion 220, respectively, the gate driving portion 210 and the data driving portion 220 can be controlled.

The timing control portion 240 can be configured to be combined with various processors, for example, a microprocessor, a mobile processor, an application processor, etc., depending on a device to be mounted.

Meanwhile, the host system can be, for example, a driving system that drives an electronic device to which the light emitting display apparatus 10 is applied. The electronic device can be, for example, one of a TV (Television), a navigation system, a monitor, a mobile device, and a wearable device.

The gate driving portion 210 can receive the gate control signal GCS from the timing control portion 240, generate the gate signals, and sequentially apply the gate signals to the gate lines GL. For example, the gate signals can be sequentially output from the top to the bottom in the vertical direction.

The gate driving portion 210 can be arranged, for example, on at least one side of the display region AA. In this embodiment, a case is taken as an example in which the gate driving portion 210 is configured to include first and second gate driving portions 211 and 212 arranged on both sides of the display region AA, for example, on the left and right sides of the display region AA.

The gate driving portion 210 can be formed directly in the non-display region NA on the substrate of the display panel 100, for example, in a GIP (gate-in panel) structure. In this case, the gate driving portion 210 can be formed during processes of forming elements of the display panel 100.

The gate driving portion 210 configured with the GIP structure can include, for example, a first scan driving circuit that sequentially outputs the first scan signals SC1, a second scan driving circuit that sequentially outputs the second scan signals SC2, a third scan driving circuit that sequentially outputs the third scan signals SC3, and an emission driving circuit that sequentially outputs the emission control signals EM.

Each of the first scan driving circuit to the third scan driving circuit and the first and second emission driving circuits can be configured with a shift register including a plurality of stages that output respective signals.

The gate driving portion 210 is described with further reference to FIG. 3. FIG. 3 illustrates a part of the gate driving portion 210, and for convenience of explanation, a configuration of a portion of the gate driving portion 210 that drives the n-th horizontal line of the display region AA is illustrated.

In the first gate driving portion 211 of the gate driving portion 210, for example, first to third scan stages SSC1(n) to SSC3(n) that constitute the first to third scan driving circuits, respectively, and an emission stage SEM(n) that constitute the emission driving circuit can be arranged.

In addition, in the second gate driving portion 212 of the gate driving portion 210, for example, the first to third scan stages SSC1(n) to SSC3(n) that constitute the first to third scan driving circuits, respectively, and the emission stage SEM(n) that constitute the emission driving circuits can be arranged.

The arrangement of the first to third scan stages SSC1(n) to SSC3(n) and the emission stage SEM(n) shown in FIG. 3 is an example, and they can be arranged in various combinations in the first and second gate driving portions 211 and 212.

The first scan stage SSC1(n) can generate the first scan signal SC1(n) and output it to the corresponding first scan line SCL1. Accordingly, the pixel P(n) of the n-th horizontal line can be applied with the first scan signal SC1(n).

The second scan stage SSC2(n) can generate the second scan signal SC2(n) and output it to the corresponding second scan line SCL2. Accordingly, the pixel P(n) of the n-th horizontal line can be applied with the second scan signal SC2(n).

The third scan stage SSC3(n) can generate the third scan signal SC3(n) and output it to the corresponding third scan line SCL3. Accordingly, the pixel P(n) of the n-th horizontal line can be applied with the third scan signal SC3(n).

The emission stage SEM(n) can generate the emission control signal EM(n) and output it to the corresponding emission control line EML. Accordingly, the pixel P(n) of the n-th horizontal line can be applied with the emission control signal EM(n).

Meanwhile, referring to FIG. 3, the initialization voltage line ViniL can be arranged between the gate driving portion 210 and the display region AA.

The initialization voltage line ViniL can supply the initialization voltage Vini from the power supply portion 280 to the pixels P within the display region AA.

In FIG. 3, the initialization voltage line ViniL is illustrated as being located on each of both the left and right sides of the display region AA, but not limited thereto, and the initialization voltage line ViniL can be located on the left or right side.

Furthermore, referring to FIG. 3, one or more optical regions OA1 and OA2 can be disposed in the display region AA.

The one or more optical regions OA1 and OA2 can be arranged to overlap one or more optical electronic devices, for example, a photographing device such as a camera (or image sensor), and/or a detection sensor such as a proximity sensor and an illuminance sensor. For the operation of the optical electronic device, the one or more optical regions OA1 and OA2 can have a light-transmitting structure formed therein and can have transmittance of a certain level or higher. In other words, a number of pixels P per unit area in the one or more optical regions OA1 and OA2 can be smaller than a number of pixels P per unit area in a regular region excluding the optical regions OA1 and OA2 in the display region AA. That is, a resolution of the one or more optical regions OA1 and OA2 can be lower than a resolution of the regular region within the display region AA.

Referring back to FIG. 1, the data driving portion 220 can receive the image data Do and the data control signal DCS from the timing control portion 240, and in response to the data control signal DCS, the data driving portion 220 can convert the image data Do into analog image data, i.e., data voltages Vdata, and outputs them to the respective data lines DL.

The power supply portion 280 can generate DC power for driving the pixel array and the driving circuit portion of the display panel 100 using, for example, a DC-DC converter. The DC-DC converter can include a charge pump, a regulator, a buck converter, a boost converter, etc.

The power supply portion 280 can receive, for example, a power voltage Vcc that is a driving voltage for driving the light emitting display apparatus 10 from the host system, and generate the DC voltages such as a gate low voltage VGL, a gate high voltage VGH, a high-potential driving voltage EVDD, a low-potential driving voltage EVSS, and an initialization voltage Vini. The gate low voltage VGL and the gate high voltage VGH can be supplied to the gate driving portion 210. The high-potential driving voltage EVDD, the low-potential driving voltage EVSS, and the initialization voltage Vini can be supplied in common to the pixels P in the display panel 100.

Hereinafter, the emission stage constituting the emission driving circuit of this embodiment can be described with further reference to FIG. 4. FIG. 4 is a view schematically illustrating a structure of an emission stage of an emission driving circuit according to a first embodiment of the present disclosure.

In FIG. 4, for convenience of explanation, the n-th emission stage SEM(n), which generates the emission control signal (EM: EM(n)) that drives the n-th horizontal line of the display region AA, among the emission stages SEM forming the emission driving circuit is illustrated as an example.

Referring to FIG. 4 along with FIGS. 1 to 3, the emission driving circuit can include a plurality of emission stages SEM that output a plurality of emission control signals EM corresponding to a plurality of emission control lines EML arranged in the display region AA, respectively.

Regarding the configuration of the emission stage SEM, the n-th emission stage SEM(n) can be described as an example. The emission stage SEM(n) can include a buffer portion (or output buffer portion) that generates and outputs the corresponding emission control signal EM(n), and a control portion that controls an output operation of the buffer portion.

Meanwhile, in this embodiment, the buffer portion can be configured to output a carry signal CR(n) separately from the emission control signal EM(n). The carry signal CR(n) can be output with substantially the same timing as the emission control signal EM(n), and can be input to a subsequent emission stage SEM, for example, an (n+1)-th emission stage SEM. Alternatively, the buffer portion may not generate a carry signal CR(n), and in this case, the emission control signal EM(n) can be used as a carry signal.

The buffer portion can include, for example, a first buffer transistor Tb1, which can be a pull-down transistor, controlled by a Q1 node (or Q node), and a second buffer transistor Tb2, which can be a pull-up transistor, controlled by a QB1 node (or QB node).

Meanwhile, the buffer portion can further include a third buffer transistor Tb3, which can be a pull-down transistor, connected in parallel with the first buffer transistor Tb1 and controlled by the QB1 node. The third buffer transistor Tb3 can be connected in parallel with the first buffer transistor Tb1 to form a transmission gate circuit.

The first to third buffer transistors Tb1 to Tb3 configured as above can output the emission control signal EM(n) from a first output terminal NO1 according to output control of the Q1 node and the QB1 node. The first to third buffer transistors Tb1 to Tb3 can constitute a first buffer portion that outputs the emission control signal EM(n).

Furthermore, the buffer portion can include, for example, a fourth buffer transistor Tb4, which can be a pull-down transistor, controlled by the QB1 node, and a fifth buffer transistor Tb5, which can be a pull-up transistor, controlled by the QB1 node.

The fourth and fifth buffer transistors Tb4 and Tb5 configured as above can output the carry signal CR(n) from a second output terminal NO2 according to output control of the QB1 node. The fourth and fifth buffer transistors Tb4 and Tb5 can constitute a second buffer portion that outputs the carry signal CR(n).

Furthermore, the buffer portion can include, for example, a Q capacitor CQ connected between the Q1 node and the first output terminal NO1.

Furthermore, the buffer portion can include, for example, a capacitor circuit CC connected between the QB1 node and the first output terminal NO1. The capacitor circuit CC can include, for example, a plurality of capacitors Ca connected in parallel with each other.

In this case, the capacitor circuit CC can be connected in series with the Q capacitor CQ with the first output terminal NO1 interposed therebetween. In other words, the capacitor circuit CC and the Q capacitor CQ connected at the first output terminal NO1 can be connected in series between the QB1 node and the Q1 node.

A number of the capacitors Ca constituting the capacitor circuit CC can be two or more. For example, the number of the capacitors Ca forming the capacitor circuit CC can be two or more and eighteen or less, but not limited thereto.

Meanwhile, for convenience of explanation, an example in which four capacitors Ca are arranged is illustrated in FIG. 4.

The control portion of the emission stage SEM can include, for example, a plurality of control transistors Ts1, Ts2, Ts3, and Ts4. The control transistors Ts1, Ts2, Ts3, and Ts4 can include, for example, first, second, third, and fourth control transistors Ts1, Ts2, Ts3, and Ts4.

Furthermore, the control portion of the emission stage SEM can further include, for example, a diode D. For example, the diode D can be configured as a transistor with a diode connection structure, for example.

As such, the diode D can be configured as a transistor, so that the diode D can be considered to constitute the control transistors of the emission stage SEM.

Meanwhile, the transistors Tb1 to Tb5, and Ts1 to Ts4, and the diode D constituting the emission stage SEM(n) can each be configured as a P-type transistor or an N-type transistor. In addition, each of the transistors Tb1 to Tb5, and Ts1 to Ts4, and the diode D constituting the emission stage SEM(n) can be a transistor using an oxide semiconductor or a transistor using polycrystalline silicon.

In this embodiment, among the transistors Tb1 to Tb5, and Ts1 to Ts4, and the diode D constituting the emission stage SEM(n), the third and fourth buffer transistors Tb3 and Tb4, the third control transistor Ts3, and the diode D can be configured as N-type transistors including an oxide semiconductor layer, and the first, second, and fifth buffer transistors Tb1, Tb2, and Tb5, and the first, second, and fourth control transistors Ts1, Ts2, and Ts4 can be configured as P-type transistors including a polycrystalline silicon layer, but not limited thereto.

In addition, the third buffer transistor Tb3, the fourth buffer transistor Tb4, and the third control transistor Ts3 can be configured as transistors having a double-gate structure, but not limited thereto. In this regard, each of the third buffer transistor Tb3, the fourth buffer transistor Tb4, and the third control transistor Ts3 of the double-gate structure can include a first gate electrode connected to a control node, and a second gate electrode directly connected to a source electrode.

For example, the first gate electrode of the third buffer transistor Tb3 can be connected to the QB1 node, and the second gate electrode of the third buffer transistor Tb3 can be connected to the source electrode of the third buffer transistor Tb3. Furthermore, the first gate electrode of the fourth buffer transistor Tb4 can be connected to the QB1 node, and the second gate electrode of the fourth buffer transistor Tb4 can be connected to the source electrode of the fourth buffer transistor Tb4. Furthermore, the first gate electrode of the third control transistor Ts3 can be connected to the Q1 node, and the second gate electrode of the third control transistor Ts3 can be connected to the source electrode of the third control transistor Ts3.

The first buffer transistor Tb1 of the first buffer portion can, for example, pull-down drives the first output terminal NO1 in response to a signal supplied from the Q1 node to its gate electrode, and the third buffer transistor Tb3 of the first buffer portion can pull-down drive the first output terminal NO1 in response to a signal supplied from the QB1 node to its gate electrode (or its first gate electrode). In addition, the second buffer transistor Tb2 of the first buffer portion can pull-up drive the first output terminal NO1 in response to a signal from the QB1 node to its gate electrode.

For example, the first and third buffer transistors Tb1 and Tb3 connected in parallel can be configured with opposite P type and N type transistors, and their gate electrodes can be connected to the Q1 node and the QB1 node having opposite phases, so that their turn-on/turn-off states can be the same. In addition, the second buffer transistor Tb2 can be configured as a P type transistor, and its gate electrode can be connected to the QB1 node, so that its turn-on/turn-off states can be opposite to those of the first and third buffer transistors Tb1 and Tb3.

As such, the parallel circuit (i.e., the transmission gate circuit) configured with the first and third buffer transistors Tb1 and Tb3, and the second buffer transistor Tb2 can form an inverter circuit, so that when one of the parallel circuit with the first and third buffer transistors Tb1 and Tb3, and the second buffer transistor Tb2 is turned on, the other one can be turned off.

The P-type first buffer transistor Tb1 can include, for example, a drain electrode that receives a gate low voltage VGL output from the power supply portion 280, and a source electrode that is connected to the first output terminal NO1. In addition, the N-type third buffer transistor Tb3 can include, for example, a source electrode that receives the gate low voltage VGL and a drain electrode that is connected to the first output terminal NO1.

The P-type second buffer transistor Tb2 can include, for example, a drain electrode connected to the first output terminal NO1, and a source electrode provided with a gate high voltage VGH output from the power supply portion 280.

In this case, when the voltage of the Q1 node is at a low level and conversely, the voltage of the QB1 node is at a high level, the first and third buffer transistors Tb1 and Tb3 can be turned on, and conversely, the second buffer transistor Tb2 can be turned off. Accordingly, the gate low voltage VGL can be output through the first and third buffer transistors Tb1 and Tb3, so that the emission control signal EM(n) of a low level can be applied to the corresponding emission control line EML. While the low-level emission control signal EM(n) is applied (i.e., during a non-emission period), no driving current may be supplied to the light emitting diode OD of the pixel P, so that the pixel P can be in a non-emission state.

In addition, when the voltage of the Q1 node is at a high level and conversely, the voltage of the QB1 node is at a low level, the first and third buffer transistors Tb1 and Tb3 can be turned off, and conversely, the second buffer transistor Tb2 can be turned on. Accordingly, the gate high voltage VGH can be output through the second buffer transistor Tb2, so that the emission control signal EM(n) of a high level can be applied to the corresponding emission control line EML. While the high-level emission control signal EM(n) is applied (i.e., during an emission period), a driving current can be supplied to the light emitting diode OD of the pixel P, so that the pixel P can be in an emission state.

The fourth buffer transistor Tb4 of the second buffer portion can, for example, pull-down drive the second output terminal NO2 in response to a signal supplied from the QB1 node to its gate electrode. Furthermore, the fifth buffer transistor Tb5 of the second buffer portion can pull-up drive the second output terminal NO2 in response to a signal supplied from the QB1 node to its gate electrode.

For example, the fourth buffer transistor Tb4 can be configured as an N-type transistor, and its gate electrode can be connected to the QB1 node. Furthermore, the fifth buffer transistor Tb5 can be configured as a P-type transistor, and its gate electrode can be connected to the QB1 node.

As such, the fourth buffer transistor Tb4 and the fifth buffer transistor Tb5 can form an inverter circuit, so that when one of the fourth buffer transistor Tb4 or the fifth buffer transistor Tb5 is turned on, the other one can be turned off.

The N-type fourth buffer transistor Tb4 can include, for example, a source electrode that receives the gate low voltage VGL, and a drain electrode that is connected to the second output terminal NO2.

The P-type fifth buffer transistor Tb5 can include, for example, a drain electrode that is connected to the second output terminal NO2, and a source electrode that is provided with the gate high voltage VGH.

In this case, when the voltage at the QB1 node is high, the fourth buffer transistor Tb4 can be turned on, and conversely, the fifth buffer transistor Tb5 can be turned off. Accordingly, the gate low voltage VGL can be output through the fourth buffer transistor Tb4, so that the carry signal CR(n) of a low level can be generated.

In addition, when the voltage at the QB1 node is low, the fourth buffer transistor Tb4 can be turned off, and conversely, the fifth buffer transistor Tb5 can be turned on. Accordingly, the gate high voltage VGH can be output through the fifth buffer transistor Tb5, so that the carry signal CR(n) of a high level can be generated.

As described above, the outputs of the first buffer portion and the second buffer portion can be controlled according to the voltages of the Q1 node and the QB1 node that are control nodes, so that the emission control signal EM(n) can be generated and output from the first output terminal NO1, and the carry signal CR(n) can be generated and output from the second output terminal NO2. At this time, the emission control signal EM(n) and the carry signal CR(n) can have substantially the same waveform with the same timing.

The first control transistor Ts1 of the control portion can provide, for example, in response to a corresponding clock (ECLK: ECLK1), an (n−1)-th carry signal CR(n−1), which is an output signal of an (n−1)-th emission stage SEM that is an emission stage SEM arranged before the n-th emission stage SEM(n), to a Q0 node. The P-type first control transistor Ts1 can include, for example, a gate electrode that receives the clock ECLK, a drain electrode connected to the Q0 node, and a source electrode that receives the previous carry signal CR(n−1).

Here, clocks ECLK of different n-phases, for example, two phases, can be alternately input to the emission stages SEM sequentially arranged along a scan direction (e.g., a downward vertical direction). For example, a first clock ECLK1 can be input to the n-th emission stage SEM(n), and the (n−1)-th and (n+1)-th emitting stages SEM positioned before and after the n-th emission stage SEM(n) can be input with a second clock having a different phase from the first clock ECLK1.

The second control transistor Ts2 can be connected, for example, between the Q0 node and the Q1 node, and can transfer charges from the Q0 node to the Q1 node in response to the gate low voltage VGL. The second control transistor Ts2 can function as a transfer transistor.

In this regard, the P-type second control transistor Ts2 can include, for example, a gate electrode to which the gate low voltage VGL is applied, a source electrode connected to the Q0 node, and a drain electrode connected to the Q1 node.

The third control transistor Ts3 can transfer the gate low voltage VGL to a drain electrode of the diode D in response to the voltage at the Q1 node. The N-type third control transistor Ts3 can include, for example, a gate electrode connected to the Q1 node, a drain electrode connected to the diode D, and a source electrode to which the gate low voltage VGL is applied.

The fourth control transistor Ts4 can be connected in series with the third control transistor Ts3 with the diode D interposed therebetween, and can transmit the gate high voltage VGH to the QB1 node in response to the voltage at the Q0 node. The P-type fourth control transistor Ts4 can include, for example, a gate electrode connected to the Q0 node, a source electrode receiving the gate high voltage VGH, and a drain electrode connected to the diode D.

The third and fourth control transistors Ts3 and Ts4 can form an inverter circuit with the diode D interposed therebetween, and the turn-on/turn-off states of the third and fourth control transistors Ts3 and Ts4 can be reversed.

As mentioned above, the diode D can be connected between the third and fourth control transistors Ts3 and Ts4. The transistor constituting the diode D can include, for example, a gate electrode and a drain electrode commonly connected to the QB1 node, and a source electrode connected to the third control transistor Ts3.

The diode D configured as above can be configured, for example, such that its forward direction is directed from the QB1 node toward the third control transistor Ts3.

When the diode D is connected to the QB1 node in this manner, a voltage variation at the QB1 node can be mitigated.

For example, at a falling edge where the voltage of the QB1 node drops from the gate high voltage VGH to the gate low voltage VGL, falling can be delayed and a falling time can be increased by the diode D.

Accordingly, a voltage variation at the gate electrode of the second buffer transistor Tb2 that is connected to the QB1 node, i.e., a falling of voltage at the gate electrode of the second buffer transistor Tb2, can be delayed. Consequently, the gate high voltage VGH output through the second buffer transistor Tb2 can be delayed.

Accordingly, regarding the emission control signal EM(n) output from the first output terminal NO1, at a rising edge where the emission control signal EM(n) rises from the gate low voltage VGL to the gate high voltage VGH, rising can be delayed and a rising time can be increased.

As such, since the rising time of the emission control signal EM(n) can be increased, a rapid variation of voltage in the emission control signal EM(n) can be mitigated (or reduced).

As mentioned above, the Q capacitor CQ can be connected between the Q1 node and the first output terminal NO1. Here, a capacitance of the Q capacitor CQ can be set to be larger than a capacitance of the storage capacitor Cst in the pixel P.

In this regard, while the gate low voltage VGL is output through the first and third buffer transistors Tb1 and Tb3, the Q1 node can be bootstrapped by the Q capacitor CQ, so that the voltage of the Q1 node can be lowered to a voltage substantially lower than the gate low voltage VGL. Due to the voltage drop at the Q1 node due to the bootstrapping action, the gate low voltage VGL can be stably output from the first output terminal NO1.

Meanwhile, as mentioned above, in the emission stage SEM(n) of this embodiment, the capacitor circuit CC configured with the plurality of capacitors Ca, which are connected in parallel between the QB1 node and the first output terminal NO1, can be provided.

When the plurality of capacitors Ca are connected to the QB1 node in this way, the voltage variation of the QB1 node can be mitigated (or reduced).

For example, the plurality of capacitors Ca can be connected to the QB1 node, so that a capacitance for the QB1 node can be increased. Consequently, at the falling edge where the voltage of the QB1 node drops from the gate high voltage VGH to the gate low voltage VGL, falling at the QB1 node can be delayed and the falling time at the QB1 node can be increased by the parallel-connected capacitors Ca.

Accordingly, the voltage variation at the gate electrode of the second buffer transistor Tb2 connected to the QB1 node, i.e., the falling of voltage at the gate electrode of the second buffer transistor Tb2, can be delayed. Thus, the gate high voltage VGH output through the second buffer transistor Tb2 can be delayed.

Accordingly, the emission control signal EM(n) output from the first output terminal NO1 can have the delayed rising and increased rising time at the rising edge where it rises from the gate low voltage VGL to the gate high voltage VGH.

As such, since the rising time of the emission control signal EM(n) can be increased, the rapid voltage variation of the emission control signal EM(n) can be mitigated (or reduced).

As described above, in the emission stage SEM(n) of this embodiment, the plurality of capacitors Ca that are connected in parallel with each other and are coupled to the QB1 node can be provided. Furthermore, the diode D connected to the QB1 node can be provided.

Accordingly, the falling time of the QB1 node can be increased, and thus the rising time of the emission control signal EM(n) can be increased, thereby improving the rapid voltage variation of the emission control signal EM(n).

Therefore, the problem that touch noise of the light emitting display apparatus 10 increases due to the rapid voltage variation of the emission control signal EM(n) and thus touch performance is degraded can be alleviated (or reduced).

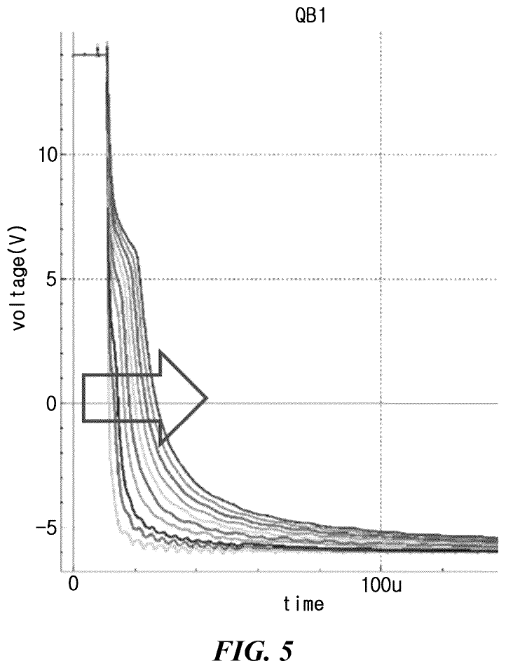

The improvement of the rapid voltage variation of the emission control signal EM(n) of this embodiment can be described with further reference to FIGS. 5 to 8.

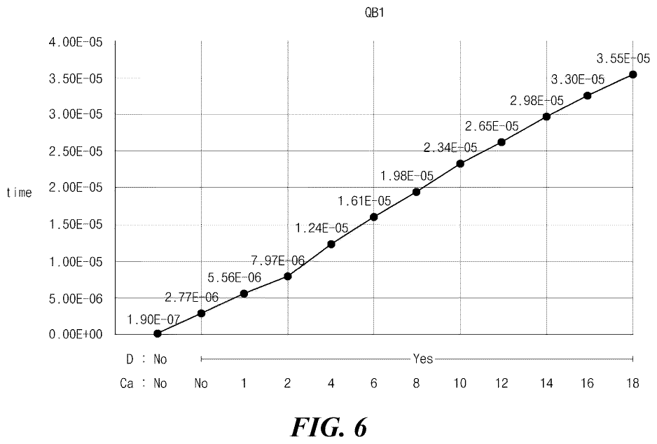

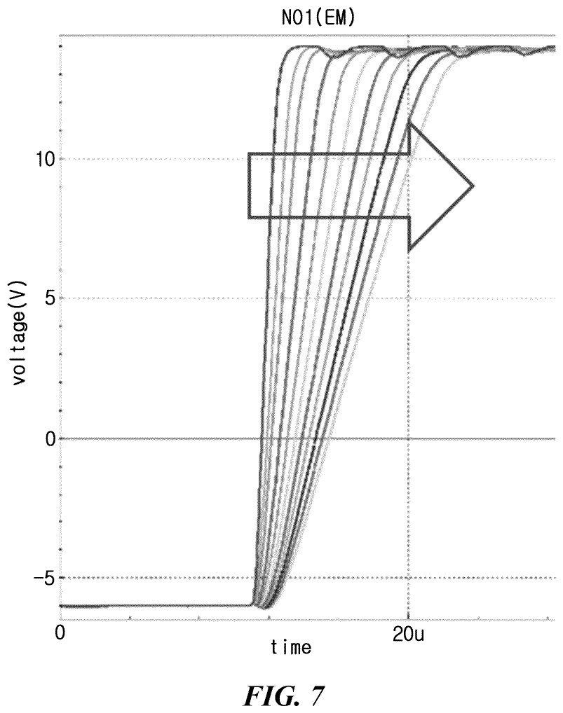

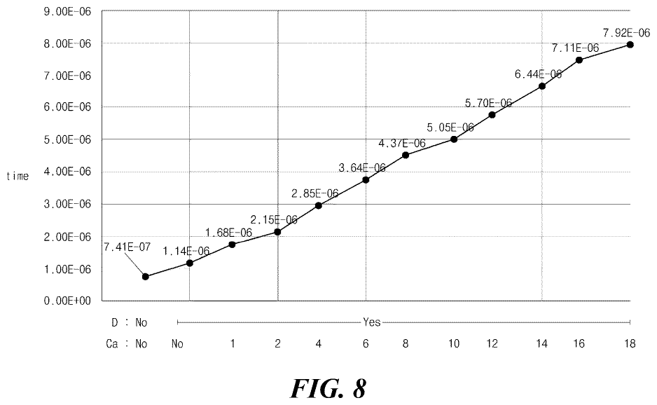

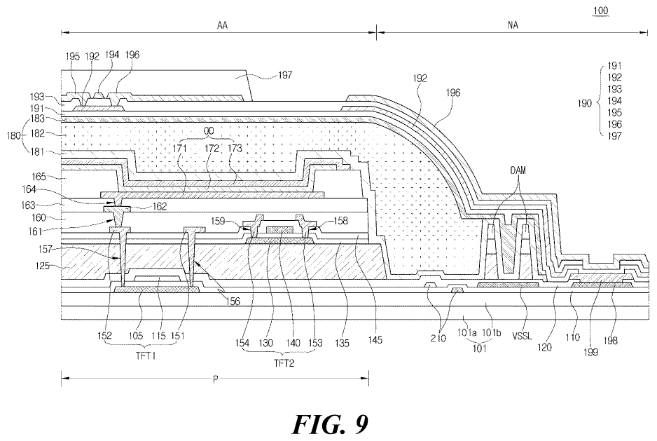

FIGS. 5 to 8 show experimental results for a falling of a QB1 node and a rising of an emission control signal in an emission stage according to a first embodiment of the present disclosure. Specifically, FIG. 5 is a view illustrating waveforms of voltage falling at a QB1 node according to presence or absence of a diode and a number of a capacitor(s) in an emission stage according to a first embodiment of the present disclosure. FIG. 6 is a view illustrating times of voltage falling at a QB1 node according to presence or absence of a diode and a number of a capacitor(s) in an emission stage according to a first embodiment of the present disclosure. FIG. 7 is a view illustrating waveforms of voltage rising at a first output terminal according to presence or absence of a diode and a number of a capacitor(s) in an emission stage according to an embodiment of the present disclosure. FIG. 8 is a view illustrating times of voltage rising at a first output terminal according to presence or absence of a diode and a number of a capacitor(s) in an emission stage according to a first embodiment of the present disclosure.

Meanwhile, in FIG. 5, the waveforms of voltage falling at the QB1 node for eleven samples according to the presence or absence of the diode D and the number of the capacitor(s) Ca are illustrated. In the direction of the arrow from left to right, the waveform of voltage falling for a sample that has no diode D and has no capacitor Ca, and the waveforms of voltage falling for samples that each have the diode D and each have an increasing number of the capacitor(s) Ca (e.g., the number of the capacitor(s) Ca is 0, 1, 2, 4, 6, 8, 10, 12, 14, and then 16) are illustrated.

Similarly, in FIG. 7, the waveforms of voltage rising at the first output terminal NO1 for eleven samples according to the presence or absence of the diode D and the number of capacitor(s) Ca are illustrated. In the direction of the arrow from left to right, the waveform of voltage rising for a sample that has no diode D and has no capacitor Ca, and the waveforms of voltage rising for samples that each have the diode D and each have an increasing number of capacitor(s) Ca (e.g., the number of capacitor(s) Ca is 0, 1, 2, 4, 6, 8, 10, 12, 14, and then 16) are illustrated.

Meanwhile, in FIG. 6, the times of voltage falling at the QB1 node for twelve samples according to the presence or absence of the diode D and the number of the capacitor(s) Ca are illustrated. The time of voltage falling for a sample that has no diode D and has no capacitor Ca, and the times of voltage falling for samples that each have the diode D and each have an increasing number of the capacitor(s) Ca (e.g., the number of the capacitor(s) Ca is 0, 1, 2, 4, 6, 8, 10, 12, 14, 16, and then 18) are illustrated.

Similarly, in FIG. 8, the times of voltage rising at the first output terminal NO1 for twelve samples according to the presence or absence of the diode D and the number of the capacitor(s) Ca are illustrated. The time of voltage rising for a sample that has no diode D and has no capacitor Ca, and the times of voltage rising for samples that each have the diode D and each have an increasing number of the capacitor(s) Ca (e.g., the number of the capacitor(s) Ca is 0, 1, 2, 4, 6, 8, 10, 12, 14, 16, and then 18) are illustrated.

In FIGS. 6 and 8, “No” for the diode D indicates the absence of the diode D, and “Yes” for the diode D indicates the presence of the diode D, and “No” for the capacitor Ca indicates the absence of the capacitor Ca.

Referring to FIGS. 5 and 6, in the case where the diode D and the capacitor Ca are not provided, the voltage at the QB1 node rapidly falls.

However, as the diode D is provided and the number of the capacitor(s) Ca increases, the voltage falling at the QB1 node can be delayed, resulting in an increase in falling time.

In addition, referring to FIGS. 7 and 8, in the case where the diode D and the capacitor Ca are not provided, the voltage at the QB1 node rapidly falls, so that the voltage at the first output terminal NO1, i.e., the voltage of the emission control signal EM rapidly rises.

However, as the diode D is provided and the number of the capacitors Ca increases, the voltage falling at the QB1 node can be delayed and the falling time can be increased, so that the voltage rising of the first output terminal NO1, i.e., the voltage rising of the emission control signal EM can be delayed and the rising time can be increased.

Hereinafter, an example of a cross-sectional structure of the display panel 100 of this embodiment is described with further reference to FIG. 9. FIG. 9 is a cross-sectional view schematically illustrating an example of a cross-sectional structure of a display panel according to a first embodiment of the present disclosure.

In FIG. 9, for convenience of explanation, two thin film transistors TFT1 and TFT2 are illustrated in the pixel P within the display region AA. Here, the thin film transistor TFT1 positioned relatively lower and closer to the substrate 101 is referred to as a first thin film transistor TFT1, which can be a polycrystalline silicon thin film transistor. The thin film transistor TFT2 positioned relatively upper and farther from the substrate 101 is referred to as a second thin film transistor TFT2, which can be an oxide thin film transistor.

Meanwhile, the first thin film transistor TFT1 can be a third transistor (T3 of FIG. 2), but not limited thereto. In addition, the second thin film transistor TFT2 can be a driving transistor (DT of FIG. 2), but not limited thereto.

The substrate 101 can be configured as, for example, a thin glass substrate (or glass film) or a plastic substrate (or plastic film) so as to implement flexible characteristics of the display panel 100.

Here, in a case where the substrate 101 is configured as a glass substrate, for example, the substrate 101 can have a thickness of approximately 0.2 mm.

Meanwhile, in a case where the substrate 101 is configured as a plastic substrate, for example, the substrate 101 can include at least one polyimide layer. In this embodiment, the substrate 101 configured of two polyimide layers, which are a first polyimide layer 101a and a second polyimide layer 101b, is taken as an example.

The first thin film transistor TFT1 can include a first semiconductor layer 105 disposed on the substrate 101, a first gate electrode 115 overlapping the first semiconductor layer 105 with a first insulating layer 110 interposed therebetween, and a first source electrode 151 and a first drain electrode 152 located on a fourth insulating layer 145 over the first gate electrode 115. Here, the first semiconductor layer 105 can be formed of polycrystalline silicon, but not limited thereto.

The first semiconductor layer 105 can include a central channel region and source and drain regions on both sides thereof. The first source electrode 151 and the first drain electrode 152 can be connected to the source region and the drain region of the first semiconductor layer 105 through the first and second contact holes 156 and 157 that are formed in the insulating layers 110, 120, 125, 135, and 145 located below the first source electrode 151 and the first drain electrode 152.

A second insulating layer 120 can be formed on the first gate electrode 115 of the first thin film transistor TFT1.

A first interlayered insulating layer 125 can be formed on the second insulating layer 120. The second thin film transistor TFT2 can be formed on the first interlayered insulating layer 125.

The second thin film transistor TFT2 can include a second semiconductor layer 130 on the first interlayered insulating layer 125, a second gate electrode 140 overlapping the second semiconductor layer 130 with a third insulating layer 135 interposed therebetween, and a second source electrode 153 and a second drain electrode 154 located on the fourth insulating layer 145 over the second gate electrode 140. Here, the second semiconductor layer 130 can be formed of an oxide semiconductor, but not limited thereto.

The second semiconductor layer 130 can include a central channel region and source and drain regions on both sides thereof. The second source electrode 153 and the second drain electrode 154 can be connected to the source and drain regions of the second semiconductor layer 130 through third and fourth contact holes 158 and 159 formed in the insulating layers 135 and 145 located below the second source electrode 153 and the second drain electrode 154.

A second interlayered insulating layer (or first planarization layer) 160 can be formed on the second thin film transistor TFT2.

Here, the first, second, third, and fourth insulating layers 110, 120, 135, and 145 can be formed of an inorganic insulating material such as silicon nitride or silicon oxide, but not limited thereto.

In addition, the first and second interlayered insulating layers 125 and 160 can be formed of an organic insulating material such as photo acrylic or benzocyclobutene, but not limited thereto.

A connection electrode 162 can be formed on the second interlayered insulating layer 160. The connection electrode 162 can be connected to the first drain electrode 152 through a contact hole 161 formed in the second interlayered insulating layer 160.

A third interlayered insulating layer (or second planarization layer) 163 can be formed on the connection electrode 162. The third interlayered insulating layer 163 can be formed of an organic insulating material such as photo acrylic or benzocyclobutene, but not limited thereto.

The light emitting diode OD and a bank 165 can be formed on the third interlayered insulating layer 163.

The light emitting diode OD can include an anode electrode (or first electrode) 171, a light emitting layer 172, and a cathode electrode (or second electrode) 173.

The anode electrode 171 can be connected to the connection electrode 162 through the contact hole 164 formed in the third interlayered insulating layer 163.

The bank 165 can be disposed along a boundary of the pixel P and can be formed to cover an edge of the anode electrode 171. The light emitting layer 172 can be formed on the anode electrode 171 exposed through an opening of the bank 165.

The cathode electrode 173 can be formed on the light emitting layer 172 and can be applied with the low-potential driving voltage (EVSS of FIG. 2).

An encapsulation layer 180 can be formed on the cathode electrode 173. The encapsulation layer 180 can include at least one inorganic encapsulation layer and at least one organic encapsulation layer, but not limited thereto. In this disclosure, a structure of the encapsulation layer 180, in which a first encapsulation layer 181, a second encapsulation layer 182, and a third encapsulation layer 183 are sequentially stacked, is described as an example.

The first encapsulation layer 181 can be formed on the substrate 101 on which the cathode electrode 173 is formed. The third encapsulation layer 183 can be formed on the substrate 101 on which the second encapsulation layer 182 is formed, and can be formed to surround an upper surface, a lower surface, and a side surface of the second encapsulation layer 182 together with the first encapsulation layer 181. The first encapsulation layer 181 and the third encapsulation layer 183 can minimize or prevent external moisture or oxygen from penetrating into the light emitting diode OD. The first encapsulation layer 181 and the third encapsulation layer 183 can be formed of an inorganic insulating material capable of low-temperature deposition, such as silicon nitride, silicon oxide, silicon oxynitride, or aluminum oxide.

The second encapsulation layer 182 can acts as a buffer to relieve stress between layers due to bending of the light emitting display apparatus 10, and can flatten steps between layers. The second encapsulation layer 182 can be formed on the substrate 101 on which the first encapsulation layer 181 is formed, using a non-photosensitive organic insulating material such as acrylic resin, epoxy resin, phenolic resin, polyamide resin, polyimide resin, polyethylene, or silicon oxycarbon (SiOC), or a photosensitive organic insulating material such as photo acrylic, but not limited thereto. When the second encapsulation layer 182 is formed through an inkjet method, a dam DAM can be placed in the non-display region NA to prevent the second encapsulation layer 182 in liquid form from spreading to an edge of the substrate 101. The dam DAM can be disposed closer to the edge of the substrate 101 than the second encapsulation layer 182. By the dam DAM, the second encapsulation layer 182 can be prevented from spreading to a pad region, where a conductive pad is disposed, on an outermost edge of the substrate 101.

The dam DAM can be designed to prevent the spreading of the second encapsulation layer 182, but if the second encapsulation layer 182 is formed to exceed a height of the dam DAM during a process, the second encapsulation layer 182 as an organic layer can be exposed to an outside, so that moisture, etc., can easily penetrate into the light emitting element. To prevent this, 10 or more dam DAM can be formed in succession, but not limited thereto.

The dam DAM can be formed simultaneously with the first interlayered insulating layer 125, the second interlayered insulating layer 160, and the third interlayered insulating layer 163. When forming the first interlayered insulating layer 125, a lower layer of the dam DAM can be formed together, when forming the second interlayered insulating layer 160, a middle layer of the dam DAM can be formed together, and when forming the third interlayered insulating layer 163, an upper layer of the dam DAM can be formed together, so that the dam DAM can be formed in a triple laminated structure. As another example, the dam DAM can be formed with one or two of the first, second, and third interlayered insulating layers 125, 160, and 163.

Accordingly, the dam DAM can be formed of the same material as the first interlayered insulating layer 125, the second interlayered insulating layer 160, and the third interlayered insulating layer 163, but not limited thereto.

The dam DAM can be formed to overlap a low-potential driving voltage line VSSL. For example, the low-potential driving voltage line VSSL can be formed at a lower layer of a region, where the dam DAM is located, in the non-display region NA.

The low-potential driving voltage line VSSL and the gate driving portion 210 configured in the GIP structure can be formed along a periphery of the display panel 100, and the low-potential driving voltage line VSSL can be located outside the gate driving portion 210. In addition, the low-potential driving voltage line VSSL can be connected to the cathode electrode 173 to apply the low-potential driving voltage EVSS. The gate driving portion 210 is simply shown in a planar and cross-sectional manner in the drawings, but can be configured with the same structure as the first thin film transistor TFT1 and/or the second thin film transistor TFT2 of the display region AA.

A touch layer (or touch element layer) 190 can be disposed on the encapsulation layer 180. In the touch layer 190, a touch buffer layer 191 can be positioned between a touch sensor metal including touch electrode connection lines 192 and 194 and touch electrodes 195 and 196, and the cathode electrode 173 of the light emitting diode OD.

The touch buffer layer 191 can block a chemical solution (developer, etchant, etc.) used in a manufacturing process of the touch sensor metal disposed on the touch buffer layer 191 or moisture from the outside from penetrating into the light emitting layer 172 containing an organic material. Accordingly, the touch buffer layer 191 can prevent damage to the light emitting layer 172 that is vulnerable to the chemical solution or moisture.

According to a mutual-capacitance-based touch sensor structure, the touch electrodes 195 and 196 can be disposed on the touch buffer layer 191, and the touch electrodes 195 and 196 can be arranged to cross each other.

The touch electrode connection lines 192 and 194 can electrically connect the touch electrodes 195 and 196. One of the touch electrode connection lines 192 and 194, and the touch electrodes 195 and 196 can be located at different layers with a touch insulation layer 193 interposed therebetween. In addition, one of the touch electrode connection lines 192 and 194 and the other of the touch electrode connection lines 192 and 194 can be located at different layers with the touch insulation layer 193 interposed therebetween.

The touch electrode connection lines 192 and 194 can be arranged to overlap the bank 165, thereby preventing decrease in aperture ratio, but not limited thereto.

Meanwhile, a part of the touch electrodes 195 and 196 and a part of the touch electrode connection line 192 can extend along the top and side surfaces of the encapsulation layer 180 and the top and side surfaces of the dam DAM and be electrically connected to a touch driving circuit through a touch pad 198 and 199.

A part of the touch electrodes 195 and 196 and a part of the touch electrode connection line 192 can receive a touch driving signal from the touch driving circuit and transmit it to the touch electrodes 195 and 196, and can transmit a touch sensing signal detected by the touch electrodes 195 and 196 to the touch driving circuit.

In this regard, for example, a driving IC (e.g., data IC, etc.) of the data driving portion 220 including the touch driving circuit can be configured in a COF type and connected to the non-display region NA of the substrate 101 of the display panel 100, and in this case, an end of the touch pads 198 and 199 can be connected to a flexible circuit film on which the driving IC is mounted, so that a signal can be transmitted.

A touch protective layer 197 can be disposed on the touch electrodes 195 and 196. In the drawing, the touch protective layer 197 is shown as being disposed only on the touch electrodes 195 and 196, but not limited thereto, and the touch protective layer 197 can extend before or after the dam DAM to be disposed on the touch electrode connection line 192.

In addition, a color filter can be disposed on the encapsulation layer 180. The color filter can be positioned on the touch layer 190, or between the encapsulation layer 180 and the touch layer 190.

As described above, in this embodiment, the plurality of capacitors Ca connected in parallel with each other and coupled to the QB1 node can be provided in the emission stage SEM, and the diode D connected to the QB1 node can be provided in the emission stage SEM.

Accordingly, the falling time of the QB1 node can be increased, and thus the rising time of the emission control signal EM can be increased, thereby improving the rapid voltage variation of the emission control signal EM.

Therefore, the touch noise of the light emitting display apparatus 10 that increases due to the rapid voltage variation of the emission control signal EM can be reduced, thereby improving the degradation of touch performance.

### Second Embodiment

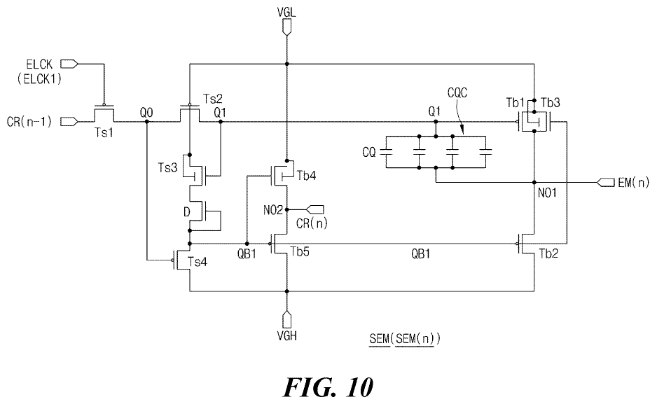

FIG. 10 is a view schematically illustrating an example of a structure of an emission stage of an emission driving circuit according to a second embodiment of the present disclosure.

In the following description, detailed explanations of components identical or similar to those of the first embodiment described above can be omitted.

In this embodiment, the emission stage (SEM: SEM(n)) can be equipped with the diode D connected to the QB1 node, similar to the first embodiment.

Meanwhile, unlike the first embodiment, the emission stage SEM(n) of this embodiment can be equipped with the Q capacitor circuit CQC configured with the plurality of Q capacitors CQ connected in parallel between the Q1 node and the first output terminal NO1.

As such, in this embodiment, instead of providing the capacitor circuit CC configured with the plurality of capacitors (Ca in FIG. 4) coupled to the QB1 node and connected in parallel to each other in the first embodiment, the plurality of Q capacitors CQ connected in parallel and coupled to the Q1 node can be provided. A number of the Q capacitor(s) CQ arranged in this manner and constituting the Q capacitor circuit CQC can be 2 or more. For example, the number of the Q capacitors CQ constituting the Q capacitor circuit CQC can be two or more and twenty or less, but not limited thereto.

Meanwhile, for convenience of explanation, an example where four Q capacitors CQ are arranged is illustrated in FIG. 10.

When the plurality of Q capacitors CQ are connected to the Q1 node in this manner, the voltage variation at the Q1 node can be mitigated (or reduced).

For example, the plurality of Q capacitors CQ can be connected to the Q1 node, so that a capacitance for the Q1 node can be increased. Consequently, at the falling edge where the voltage at the Q1 node drops from the gate high voltage VGH to the gate low voltage VGL, falling can be delayed and the falling time can be increased by the parallel-connected Q capacitors CQ.

Accordingly, the voltage variation at the gate electrode of the first buffer transistor Tb1 connected to the Q1 node, i.e., the falling of voltage at the gate electrode of the first buffer transistor Tb1, can be delayed. Thus, the gate high voltage VGH output through the second buffer transistor Tb2 can be delayed.

Accordingly, the emission control signal EM(n) output from the first output terminal NO1 can have the delayed rising and increased rising time at the rising edge where it rises from the gate low voltage VGL to the gate high voltage VGH.

As such, since the rising time of the emission control signal EM(n) can be increased, the rapid voltage variation of the emission control signal EM(n) can be mitigated (or reduced).

As described above, in the emission stage SEM(n) of this embodiment, the plurality of Q capacitors CQ that are connected in parallel with each other and are coupled to the Q1 node can be provided. Furthermore, the diode D connected to the QB1 node can be provided.

Accordingly, the falling time of the Q1 node can be increased, and thus the rising time of the emission control signal EM(n) can be increased, thereby improving the rapid voltage variation of the emission control signal EM(n).

Therefore, the problem that touch noise of the light emitting display apparatus 10 increases due to the rapid voltage variation of the emission control signal EM(n) and thus touch performance is degraded can be alleviated (or reduced).

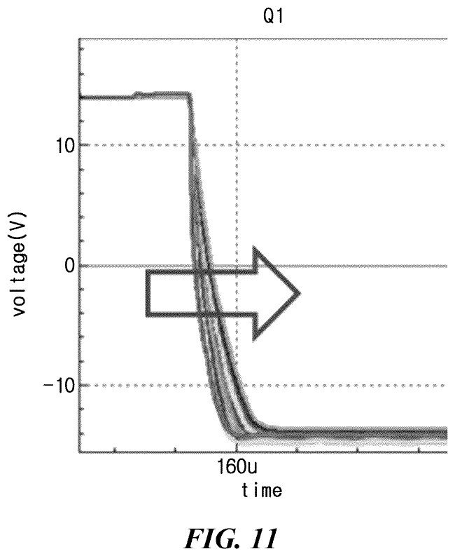

The improvement of the rapid voltage variation of the emission control signal EM(n) of this embodiment can be described with further reference to FIGS. 11 to 14.

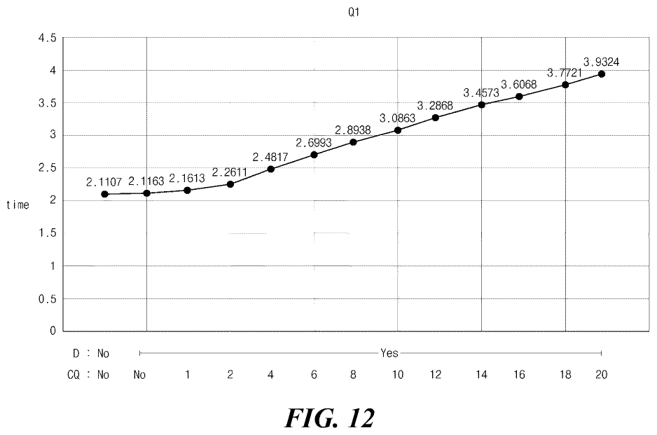

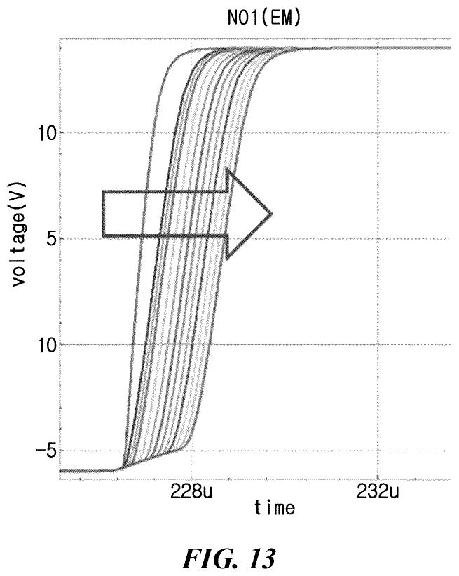

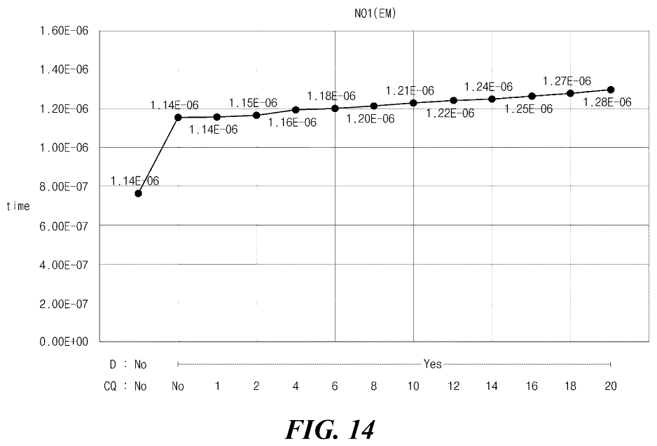

FIGS. 11 to 14 show experimental results for a falling of a Q1 node and a rising of an emission control signal in an emission stage according to a second embodiment of the present disclosure. Specifically, FIG. 11 is a view illustrating waveforms of voltage falling at a Q1 node according to presence or absence of a diode and a number of a Q capacitor(s) in an emission stage according to a second embodiment of the present disclosure. FIG. 12 is a view illustrating times of voltage falling at a Q1 node according to presence or absence of a diode and a number of a Q capacitor(s) in an emission stage according to a second embodiment of the present disclosure. FIG. 13 is a view illustrating waveforms of voltage rising at a first output terminal according to presence or absence of a diode and a number of a Q capacitor(s) in an emission stage according to a second embodiment of the present disclosure. FIG. 14 is a view illustrating times of voltage rising at a first output terminal according to presence or absence of a diode and a number of a Q capacitor(s) in an emission stage according to a second embodiment of the present disclosure.

Meanwhile, in FIG. 11, the voltage falling waveforms of the Q1 node for each of thirteen samples according to the presence or absence of the diode D and the number of the Q capacitor(s) CQ are illustrated. In the direction of the arrow from left to right, the waveform of voltage falling for a sample that has no diode D and has no Q capacitor CQ, and the waveforms of voltage falling for samples that each have the diode D and each have an increasing number of the Q capacitor(s) CQ (e.g., the number of the Q capacitor(s) CQ is 0, 1, 2, 4, 6, 8, 10, 12, 14, 16, 18, and then 20) are illustrated.

Similarly, in FIG. 13, the waveform of voltage rising at the first output terminal NO1 for thirteen samples according to the presence or absence of the diode D and the number of the Q capacitor(s) CQ are illustrated. In the direction of the arrow from left to right, the waveform of voltage rising for a sample that has no diode D and has no Q capacitor CQ, and the waveforms of voltage rising for samples that each has the diode D and each have an increasing number of the Q capacitor(s) CQ (e.g., the number of the Q capacitor(s) CQ is 0, 1, 2, 4, 6, 8, 10, 12, 14, 16, 18, and then 20) are illustrated.

Meanwhile, in FIG. 12, the times of voltage falling at the Q1 node for thirteen samples according to the presence or absence of the diode D and the number of the Q capacitor(s) CQ are illustrated. The time of voltage falling for a sample that has no diode D and has no capacitor CQ, and the times of voltage falling for samples that each have the diode D and each have an increasing number of the Q capacitor(s) CQ (e.g., the number of the Q capacitor(s) CQ is 0, 1, 2, 4, 6, 8, 10, 12, 14, 16, 18, and then 20) are illustrated.

Similarly, in FIG. 14, the times of voltage rising at the first output terminal NO1 for thirteen samples according to the presence or absence of the diode D and the number of the Q capacitor(s) CQ are illustrated. The time of voltage rising for a sample that has no diode D and has no Q capacitor CQ, and the times of voltage rising for samples that each have the diode D and each have an increasing number of the Q capacitor(s) CQ (e.g., the number of the Q capacitor(s) CQ is 0, 1, 2, 4, 6, 8, 10, 12, 14, 16, 18, and then 20) are illustrated.

In FIGS. 12 and 14, “No” for the diode D indicates the absence of the diode D, and “Yes” for the diode D indicates the presence of the diode D, and “No” for the Q capacitor CQ indicates the absence of the Q capacitor CQ.

Referring to FIGS. 11 and 12, in the case where the diode D and the Q capacitor CQ are not provided, the voltage at the Q1 node falls rapidly.

However, as the diode D is provided and the number of the Q capacitor(s) CQ increases, the voltage falling at the Q1 node can be delayed, resulting in an increase in falling time.

Referring to FIGS. 13 and 14, in the case where the diode D and the Q capacitor CQ are not provided, the voltage at the Q1 node rapidly falls, so that the voltage at the first output terminal NO1, i.e., the voltage of the emission control signal EM rapidly rises.

However, as the diode D is provided and the number of the Q capacitor(s) CQ increases, the voltage falling at the Q1 node can be delayed and the falling time can be increased, so that the voltage rising at the first output terminal NO1, i.e., the voltage rising of the emission control signal EM can be delayed and the rising time can be increased.

### Third Embodiment

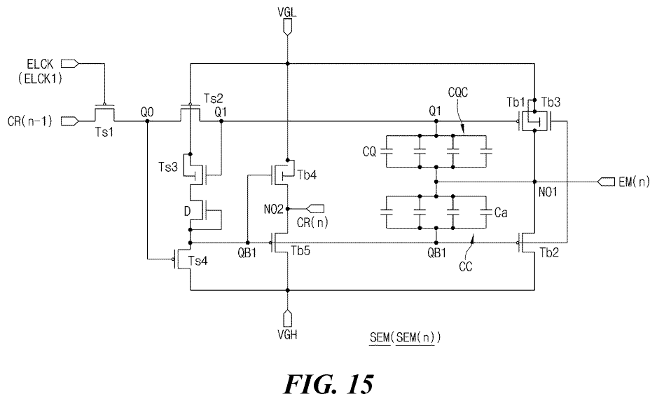

FIG. 15 is a view schematically illustrating an example of a structure of an emission stage of an emission driving circuit according to a third embodiment of the present disclosure.

In the following description, detailed explanations of components identical to or similar to those of the first and/or second embodiments described above can be omitted.

In this embodiment, the emission stage (SEM: SEM(n)) can be provided with the diode D connected to the QB1 node, similar to the first embodiment, and the capacitor circuit CC configured with the plurality of capacitors Ca connected in parallel between the QB1 node and the first output terminal NO1.

In addition, in this embodiment, the emission stage SEM(n) can be provided with the Q capacitor circuit CQC configured with the plurality of Q capacitors CQ connected in parallel between the Q1 node and the first output terminal NO1, similar to the second embodiment.

As such, in this embodiment, the diode D connected to the QB1 node and the plurality of capacitors Ca connected in parallel to each other as in the first embodiment can be provided, and the plurality of Q capacitors CQ connected in parallel to each other and coupled to the Q1 node as in the second embodiment can be provided.

Accordingly, the voltage variation at the gate electrode of the second buffer transistor Tb2 connected to the QB1 node, i.e., the falling of voltage at the gate electrode of the second buffer transistor Tb2, can be delayed. In addition, the voltage variation at the gate electrode of the first buffer transistor Tb1 connected to the Q1 node, i.e., the falling of voltage at the gate electrode of the first buffer transistor Tb1, can be delayed.

Thus, the gate high voltage VGH output through the second buffer transistor Tb2 can be further delayed.

Accordingly, the rising of the emission control signal EM(n) output from the first output terminal NO1 can be further delayed and the rising time can be increased at the rising edge where it rises from the gate low voltage VGL to the gate high voltage VGH.

As such, since the rising time of the emission control signal EM(n) can be increased, the rapid voltage variation of the emission control signal EM(n) can be further mitigated (or reduced).

As described above, in the emission stage SEM(n) of this embodiment, the plurality of capacitors Ca coupled to the QB1 node, and the plurality of Q capacitors CQ connected in parallel and coupled to the Q1 node can be provided. Furthermore, the diode D connected to the QB1 node can be provided.

Accordingly, the falling time of the QB1 node and the falling time of the Q1 node can be increased, and thus the rising time of the emission control signal EM(n) can be further increased, thereby further improving the rapid voltage variation of the emission control signal EM(n).

Therefore, the problem that touch noise of the light emitting display apparatus 10 increases due to the rapid voltage variation of the emission control signal EM(n) and thus touch performance is degraded can be further alleviated (or reduced).

As described above, according to the embodiments of the present disclosure, the emission stage can be equipped with the plurality of capacitors connected in parallel and coupled to the QB1 node, and/or the plurality of Q capacitors connected in parallel and coupled to the Q1 node. In addition, the emission stage can be equipped with the diode connected to the QB1 node.

Accordingly, the falling time of the QB1 node and/or the falling time of the Q1 node can be increased, and thus the rising time of the emission control signal at the output terminal can be increased, thereby improving the rapid voltage variation of the emission control signal.

Therefore, the problem that touch noise of the light emitting display apparatus 10 increases due to the rapid voltage variation of the emission control signal EM(n) and thus touch performance is degraded can be alleviated (or reduced).

It will be apparent to those skilled in the art that various modifications and variation can be made in the present disclosure without departing from the spirit or scope of the disclosure. Thus, it is intended that the present disclosure cover the modifications and variations of this disclosure including those of the appended claims and their equivalents.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display apparatus, comprising:
a display panel including pixels;
a light emitting diode and a plurality of transistors electrically connected to the light emitting diode, in a pixel of the pixels; and
an emission driving circuit including an emission stage which includes a first buffer portion configured to output an emission control signal applied to the pixel,
wherein the first buffer portion includes:
a first buffer transistor connected to a Q1 node and configured to receive a gate low voltage;
a second buffer transistor connected to a QB1 node and configured to receive a gate high voltage; and
a plurality of capacitors connected in parallel with each other between the QB1 node and a first output terminal that is between the first and second buffer transistors.

2. The light emitting display apparatus of claim 1, wherein the emission stage includes a diode connected to the QB1 node.

3. The light emitting display apparatus of claim 2, wherein the diode is configured by a transistor whose drain electrode and gate electrode are connected to the QB1 node.

4. The light emitting display apparatus of claim 1, wherein the first buffer portion includes a third buffer transistor which is connected in parallel with the first buffer transistor and is coupled to the QB1 node.

5. The light emitting display apparatus of claim 1, wherein the first buffer portion includes a Q capacitor connected between the Q1 node and the first output terminal.

6. The light emitting display apparatus of claim 5, wherein the first buffer portion includes a plurality of Q capacitors connected in parallel with each other between the Q1 node and the first output terminal.

7. The light emitting display apparatus of claim 1, wherein the emission stage includes a second buffer portion configured to output a carry signal, and
wherein the second buffer portion includes:
a fourth buffer transistor connected to the QB1 node and configured to receive the gate low voltage; and
a fifth buffer transistor connected to the QB1 node and configured to receive the gate high voltage,
wherein the carry signal is output from a second output terminal between the fourth and fifth buffer transistors.

8. The light emitting display apparatus of claim 2, wherein the emission stage includes:
a first control transistor configured to receive a previous carry signal, and is connected to a Q0 node;
a second control transistor which is connected between the Q0 node and the Q1 node, and includes a gate electrode receiving the gate low voltage;
a third control transistor which includes a gate electrode connected to the Q1 node, and configured to receive the gate low voltage; and
a fourth control transistor which includes a gate electrode connected to the Q0 node, and configured to receive the gate high voltage,
wherein the diode is connected between the third and fourth control transistors.

9. The light emitting display apparatus of claim 1, wherein the display panel includes a touch element layer.

10. A light emitting display apparatus, comprising:
a display panel including pixels;
a light emitting diode and a plurality of transistors electrically connected to the light emitting diode, in a pixel of the pixels; and
an emission driving circuit including an emission stage which includes a first buffer portion configured to output an emission control signal applied to the pixel,
wherein the first buffer portion includes:
a first buffer transistor connected to a Q1 node and configured to receive a gate low voltage;
a second buffer transistor connected to a QB1 node and configured to receive a gate high voltage; and
a plurality of Q capacitors connected in parallel with each other between the Q1 node and a first output terminal that is between the first and second buffer transistors.

11. The light emitting display apparatus of claim 10, wherein the emission stage includes a diode connected to the QB1 node.

12. The light emitting display apparatus of claim 11, wherein the diode is configured by a transistor whose drain electrode and gate electrode are connected to the QB1 node.

13. The light emitting display apparatus of claim 10, wherein the first buffer portion includes a third buffer transistor which is connected in parallel with the first buffer transistor and is coupled to the QB1 node.

14. The light emitting display apparatus of claim 10, wherein the first buffer portion includes a plurality of capacitors connected in parallel with each other between the QB1 node and the first output terminal.

15. The light emitting display apparatus of claim 10, wherein the emission stage includes a second buffer portion configured to output a carry signal, and
wherein the second buffer portion includes:
a fourth buffer transistor connected to the QB1 node and configured to receive the gate low voltage; and
a fifth buffer transistor connected to the QB1 node and configured to receive the gate high voltage,
wherein the carry signal is output from a second output terminal between the fourth and fifth buffer transistors.

16. The light emitting display apparatus of claim 11, wherein the emission stage includes:
a first control transistor which receives a previous carry signal, and is connected to a Q0 node;
a second control transistor which is connected between the Q0 node and the Q1 node, and includes a gate electrode configured to receive the gate low voltage;
a third control transistor which includes a gate electrode connected to the Q1 node, and configured to receive the gate low voltage; and
a fourth control transistor which includes a gate electrode connected to the Q0 node, and configured to receive the gate high voltage,
wherein the diode is connected between the third and fourth control transistors.

17. The light emitting display apparatus of claim 10, wherein the display panel includes a touch element layer.

18. A light emitting display apparatus, comprising:
a display panel including pixels;
a light emitting diode and a plurality of transistors electrically connected to the light emitting diode, in the pixel; and
an emission stage which outputs an emission control signal applied to the pixel,
wherein the emission stage includes:
a first buffer transistor connected to a Q1 node and configured to receive a gate low voltage;
a second buffer transistor connected to a QB1 node and configured to receive a gate high voltage; and
one or more of a plurality of capacitors connected in parallel with each other between the QB1 node and a first output terminal that is between the first and second buffer transistors or a plurality of Q capacitors connected in parallel with each other between the Q1 node and the first output terminal.

19. The light emitting display apparatus of claim 18, wherein the emission stage includes a diode connected to the QB1 node.

20. The light emitting display apparatus of claim 19, wherein the diode is configured as a transistor whose drain electrode and gate electrode are connected to the QB1 node.
